(19) United States
(12) Patent Application Publication
(10) Pub. No.: US 2012/0118344 A1
(43) Pub. Date: May 17, 2012

(54) HEAT EXCHANGER AND METHOD FOR CONVERTING THERMAL ENERGY OF A FLUID INTO ELECTRICAL POWER

(76) Inventors: Peter Schluck, Wolfschlugen (DE); Bernhard Mueller, Kempten (DE); Miroslaw Brzoza, Vaihingen/Enz (DE)

(21) Appl. No.: 13/318,997

(22) PCT Filed: May 12, 2010
(86) PCT No.: PCT/EP2010/056513

§ 371 Date: Jan. 25, 2012

(30) Foreign Application Priority Data
May 15, 2009 (DE) 10 2009 003 144.8

(51) Int. Cl. H01L 35/30

(52) U.S. Cl. 136/201; 136/205

(57) ABSTRACT

A heat exchanger for converting thermal energy of a fluid, e.g., exhaust gas of an internal combustion engine, into electrical power, has a flow channel for conveying a hot fluid, and at least one thermoelectric module for generating electrical power is thermally connected to the flow channel. The flow channel is manufactured from a ceramic material. Thermal expansion effects of the flow channel is reduced by the ceramic material of the flow channel so that the design complexity for converting thermal energy into electrical power is reduced.

### BACKGROUND OF THE INVENTION

1. Field of the Invention

The present invention relates to a heat exchanger and a method for converting thermal energy of a fluid into electrical power, with the aid of which the thermal energy of the fluid is convertible into electrical power with the aid of a thermoelectric module, in particular in an exhaust gas system of a motor vehicle connected to an internal combustion engine.

2. Description of Related Art

Published U.S. patent application document U.S. 2005/0172993 A1 describes a heat exchanger for an exhaust gas system of a motor vehicle. The heat exchanger has a flow channel manufactured from austenitic steel for hot exhaust gas. A thermoelectric module for generating electrical power is thermally connected to the flow channel. With the aid of a metal strip, a passive cooler is pressed against each thermoelectric module, the thermoelectric module being designed to be movable between the flow channel and the passive cooler.

One disadvantage of such a heat exchanger is that a high design complexity is required to prevent damage to the thermoelectric module due to thermal expansion effects of the flow channel, for example.

### BRIEF SUMMARY OF THE INVENTION

An object of the present invention is to create a heat exchanger and a method for converting thermal energy of a fluid into electrical power, with the aid of which the design complexity of converting thermal energy into electrical power may be reduced.

The heat exchanger according to the present invention, which may be used in particular for converting thermal energy of a fluid, preferably exhaust gases of an internal combustion engine, into electrical power, has a flow channel for conveying a hot fluid. At least one thermoelectric module for generating electrical power is thermally connected to the flow channel. According to the present invention, the flow channel is manufactured from a ceramic material.

Thermal expansion of the flow channel may be greatly reduced because of the ceramic material of the flow channel, so that structurally complex designs for compensating for the thermal expansion effects of the flow channel are not necessary. A high burden on the thermoelectric module due to shear stresses created by thermal expansion on the hot side of the thermoelectric module may at least be reduced. The design complexity of converting thermal energy into electrical power may thereby be reduced. Sintered materials in particular may be used as the ceramic material. Ceramic materials having a high thermal conductivity, such as SiC, which has a thermal conductivity of approximately 80 W/m²K and thus has a higher thermal conductivity than stainless steel, are preferred in particular. At the same time the ceramic flow channel is extremely sturdy with respect to thermal and corrosive stresses, so that a long lifetime of the heat exchanger is ensured. In particular the flow channel may have a particularly simple design as a geometric hollow cylinder, for example, so that the ceramic flow channel may be manufactured from extruded profiles. The thermoelectric module is connected to a ceramic pipe, in particular both radially on the inside and radially on the outside, with one of these ceramic pipes forming a channel wall of the flow channel.

The flow channel is preferably connected directly to the thermoelectric module, the thermoelectric module being connected to the flow channel, in particular being integrally joined, in particular by soldering. The thermoelectric module may have a plurality of semiconductor elements, in particular P semiconductors and N semiconductors, the P semiconductors and N semiconductors being situated alternatingly. Two neighboring semiconductors may be connected by a metal bridge, so that a plurality of semiconductor elements may be connected in series. The semiconductor elements are clamped between two ceramic disks, for example, and may be encapsulated with the aid of a metallic sleeve. The thermoelectric module may be integrally joined with the ceramic flow channel via the metallic sleeve in a particularly simple manner, in particular by soldering. If necessary, the ceramic flow channel may first be metalized on the surface facing the thermoelectric modules to facilitate the integral joint. Through direct contact of the thermoelectric module with the flow channel, additional function elements between the flow channel and the thermoelectric module are avoided, so that the thermal conduction resistance between the hot fluid and the thermoelectric module may be reduced.

The flow channel in particular is designed in such a way that the flow channel is in direct contact with the hot fluid during operation. Additional function elements between the hot fluid and the flow channel are thereby avoided, so that the thermal conduction resistance between the flow channel and the hot fluid may be minimized.

In a preferred specific embodiment, the thermoelectric module has at least one semiconductor element, the semiconductor element being connected directly to the flow channel, in particular the semiconductor element being integrally joined with the flow channel, in particular by soldering. The ceramic flow channel may thus be used instead of a ceramic disk of the semiconductor element, which would otherwise be provided. The ceramic disk and a metallic sleeve of the thermoelectric module may be eliminated in this way. The thermal conduction resistance between the flow channel and the semiconductor elements of the thermoelectric module is minimized because the semiconductor elements may be connected directly to the ceramic flow channel. Metal bridges provided between two neighboring semiconductor elements in particular may be used for an integral joint with the ceramic flow channel. The metal bridges may thus at the same time be used as solder for a soldered connection between the semiconductor elements and the ceramic flow channel. The semiconductor elements are connected to a ceramic pipe in particular both radially on the inside and radially on the outside, one of these ceramic pipes forming a channel wall of the flow channel. All the semiconductor elements of the thermoelectric module are preferably connected directly to the flow channel in particular. This results in a more homogeneous design, which is simple to design structurally and easy to implement with regard to manufacturing.

The thermoelectric module is preferably situated radially on the outside of the flow channel. The flow channel may thus have the hot fluid flowing through it radially on the inside while the thermoelectric modules may be connected to the ceramic flow channel radially on the outside of the flow channel. For the thermoelectric modules, this yields a comparatively large outside surface facing away from the flow channel and results in improved cooling of the thermoelectric modules. It is possible that passive cooling, for example, through natural convection alone, is sufficient to achieve an adequately great temperature difference for the thermoelectric module, resulting in an accordingly high electrical current of the thermoelectric module. The quantity of electrical power generated by the thermoelectric module may be thereby increased.

A cooling channel is preferably provided for cooling the at least one thermoelectric module, the channel being contacted thermally with the thermoelectric module. The side of the thermoelectric module facing away from the flow channel may be strongly cooled, in particular by the cooling channel, so that a particularly great temperature difference is established for the thermoelectric module. This increases the flow of current, which is generatable by the thermoelectric module. Ambient air may be used as the cooling media of the cooling channel. It is also possible to use the hot fluid of the flow channel, in particular after additional cooling with the aid of a cooler as the cooling medium of the cooling channel. The cooling channel is designed in particular in such a way that the cooling medium of the cooling channel flows through the cooling channel in countercurrent with the hot fluid of the flow channel. Therefore an essentially constant temperature difference over the length of the flow channel may be provided for the thermoelectric modules or semiconductor elements situated along the flow path. This results in essentially uniform power generation with the aid of the thermoelectric modules along the flow path.

The cooling channel is particularly preferably manufactured from a ceramic material. This yields essentially the same advantages as those described above on the basis of the ceramic flow channel. In particular, the design complexity for converting thermal energy into electrical power may be reduced and the thermal conduction resistance between the thermoelectric module and the ceramic cooling channel may be reduced. In principle it is sufficient if only the side of the flow channel and/or of the cooling channel facing the thermoelectric module is manufactured from a ceramic material. All the bordering walls in the radial direction of the flow channel and/or of the cooling channel are preferably manufactured from a ceramic material. This allows the use of comparable manufacturing methods for the flow channel and/or the cooling channel, so that the heat exchanger may be manufactured better by mass production. The thermoelectric module is in particular connected to a ceramic pipe radially on the inside as well as radially on the outside, one of these ceramic pipes forming a channel wall of the flow channel and/or one of the ceramic pipes forming a channel wall of the cooling channel.

The cooling channel is particularly preferably connected directly to the thermoelectric module, the thermoelectric module in particular being integrally joined with the cooling channel, in particular by soldering. Unnecessary thermal conduction resistances between the cooling channel and the thermoelectric module may be avoided in this way.

The thermoelectric module particularly preferably has at least one semiconductor element, the semiconductor element being connected directly to the cooling channel, in particular the semiconductor element being integrally joined with the cooling channel, in particular by soldering. The cooling channel may thus be connected directly to the semiconductor elements of the thermoelectric module, so that the thermal conduction resistance between the cooling channel and the semiconductor elements is further reduced. At the same time, metal bridges between neighboring semiconductor elements may be used as solder for the integral joint of the semiconductor elements with the cooling channel. The semiconductor elements are connected to a ceramic pipe, in particular both radially on the inside and radially on the outside, one of these ceramic pipes forming a channel wall of the flow channel and/or one of the ceramic pipes forming a channel wall of the cooling channel. In particular all the semiconductor elements of the thermoelectric module are connected directly to the flow channel.

The cooling channel is preferably situated coaxially with the flow channel. Due to the coaxial placement, this yields an annular gap between the flow channel and the cooling channel, into which the at least one thermoelectric module may be inserted.

The cooling channel and/or the flow channel in particular is/are designed to be essentially ring-shaped. Due to the ring-shaped design, it is possible to provide a comparatively large surface area for the volume flow of the flow channel and/or of the cooling channel, this surface area facing the thermoelectric module. The heating power of the hot fluid of the flow channel and/or the cooling power of the cooling medium of the cooling channel may therefore be increased.

The present invention also relates to an exhaust gas system for an internal combustion engine of a motor vehicle, in which the exhaust gas system has a heat exchanger which may be designed and improved upon as described above. Exhaust gas of the internal combustion engine may flow through the flow channel of the heat exchanger. In particular the flow channel has a catalytic converter in the area of the thermoelectric modules for treating the exhaust gases, so that the exothermic energy of the catalytic converter may additionally be utilized by the thermoelectric modules. The electrical power generated by the thermoelectric modules may be used in particular to supply power to an electronic system of the motor vehicle and/or to charge an automotive battery. Due to the improved design of the heat exchanger to be used, the design complexity for converting thermal energy into electrical power may be reduced.

The present invention also relates to a method for converting thermal energy of a fluid into electrical power in which at least one thermoelectric module for generating electrical power is connected thermally to the hot fluid only via a flow channel manufactured from a ceramic material for conveying a hot fluid, in particular with the aid of a heat exchanger which may be designed and improved upon as described above. Due to the ceramic flow channel, thermal expansion effects of the flow channel may be reduced, so that the design complexity for converting thermal energy into electrical power may be reduced. The ceramic materials used are preferably manufactured by extrusion. Extruded profiles, which are overdimensioned in length in particular, may be manufactured in this way and then cut to the corresponding required length. This makes it possible to manufacture multiple flow channels and/or cooling channels from a single overdimensioned extruded profile.

### BRIEF DESCRIPTION OF THE DRAWINGS

FIG. 1 shows a schematic sectional view of a heat exchanger in a first specific embodiment.

FIG. 2 shows a schematic sectional view of a heat exchanger in a second specific embodiment.

FIG. 3 shows a schematic sectional view of a heat exchanger in a third specific embodiment.

### DETAILED DESCRIPTION OF THE INVENTION

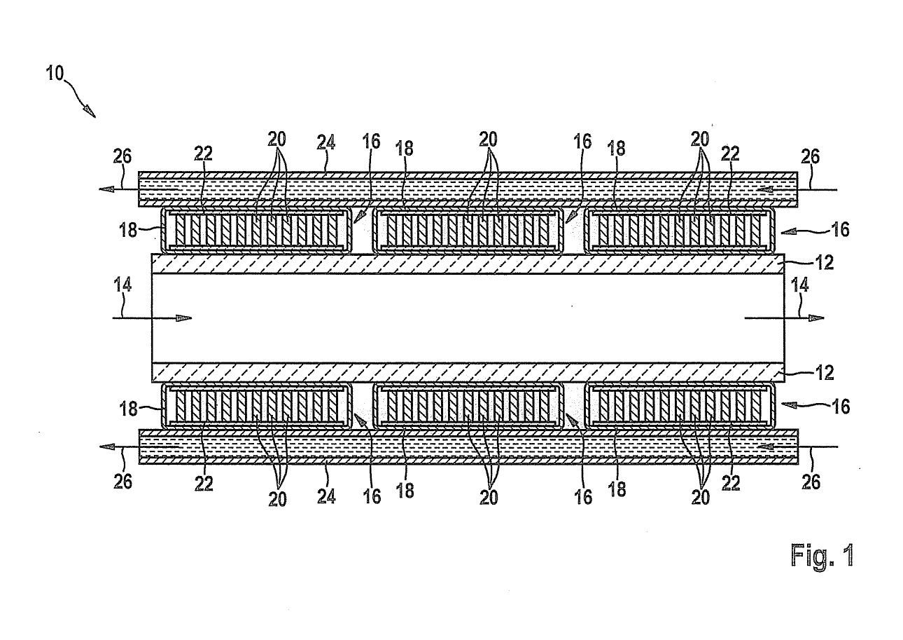

Heat exchanger 10 shown in FIG. 1 has a ceramic flow channel 12 through which a hot fluid, for example, exhaust gas from an internal combustion engine of a motor vehicle, flows in one direction of flow 14. A thermoelectric module 16 having a metallic sleeve 18 in the exemplary embodiments shown here is connected to ceramic flow channel 12.

Multiple semiconductor elements 20 clamped between two ceramic disks 22 are situated inside metallic sleeve 18. The side of thermoelectric modules 16 facing away from ceramic flow channel 12 is cooled by an annular cooling channel 24. A cooling medium flows through cooling channel 24 in a cooling direction 26 in countercurrent to direction of flow 14 of flow channel 12.

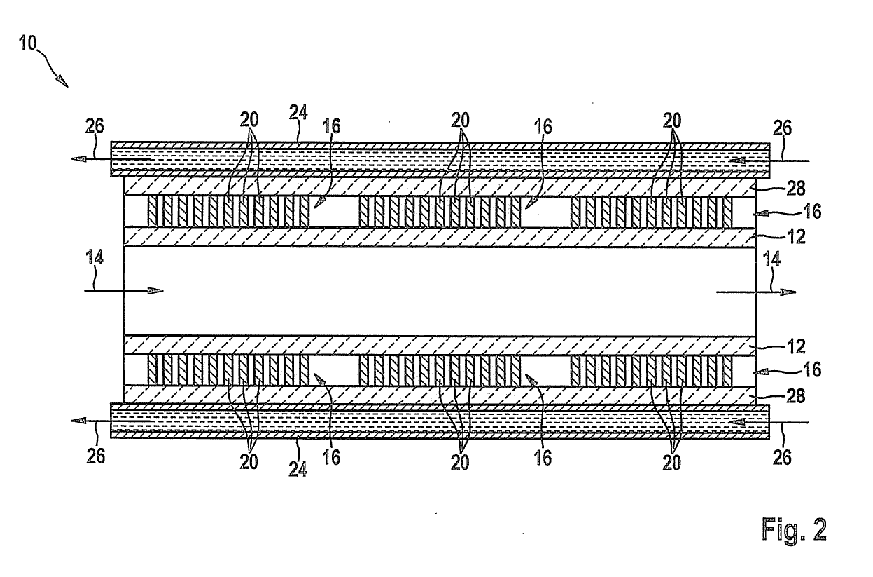

In heat exchanger 10 shown in FIG. 2, metallic sleeve 18 and ceramic disks 22 have been omitted from thermoelectric module 16 in comparison with FIG. 1, so that semiconductor elements 20 are connected directly to ceramic flow channel 12 by soldering, for example. In the exemplary embodiment shown here, semiconductor elements 20 are connected to a continuous ceramic channel 28 at both ends, the inner ceramic channel in the exemplary embodiment shown here being formed by ceramic flow channel 12. Outer ceramic channel 28 in the exemplary embodiment shown here is in direct contact with cooling channel 24, which may be made of a metallic material in the exemplary embodiment shown here.

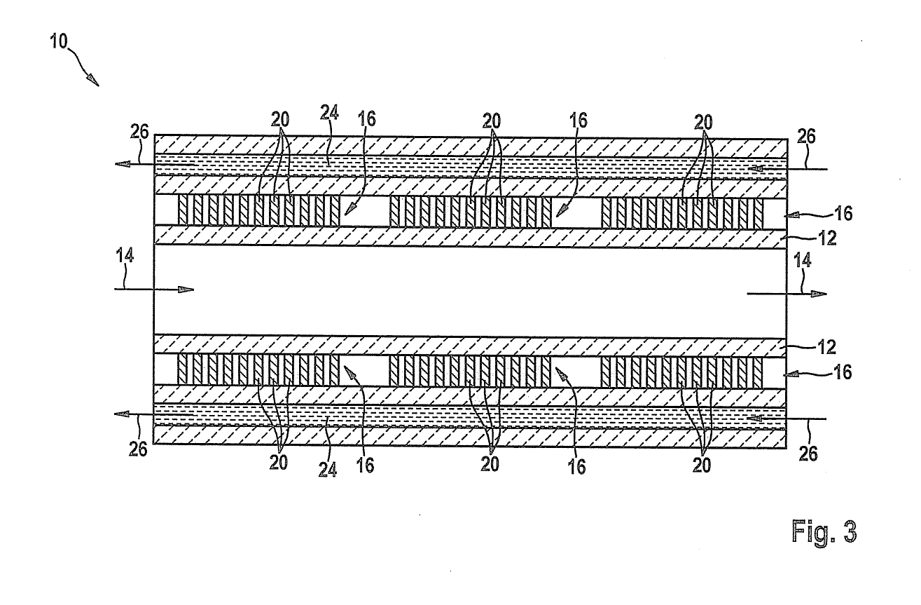

In the specific embodiment of heat exchanger 10 shown in FIG. 3, cooling channel 24 is manufactured completely from a ceramic material in comparison with the specific embodiment shown in FIG. 2. Annular cooling channel 24 in the exemplary embodiment shown here has thus an inside ceramic wall facing thermoelectric module 16 and an outside ceramic wall facing away from thermoelectric module 16. However, it is also possible for cooling channel 24 and/or flow channel 12 to be manufactured from a ceramic material only on the side facing thermoelectric module 16, while one side of cooling channel 24 and/or of flow channel 12, if present, facing away from thermoelectric module 16, may be manufactured from a different material, for example, metal. Ceramic cooling channel 24 may be soldered directly to semiconductor elements 20 of thermoelectric modules 16 in the exemplary embodiment shown here.

1-15. (canceled)

16. A heat exchanger for converting thermal energy of an exhaust gas of an internal combustion engine into electrical power, comprising:
a flow channel for conveying the exhaust gas, wherein the flow channel is made from a ceramic material; and
at least one thermoelectric module thermally connected to the flow channel for generating electrical power.

17. The heat exchanger as recited in claim 16, wherein the flow channel is directly and integrally joined with the thermoelectric module.

18. The heat exchanger as recited in claim 17, wherein the flow channel is configured to be in direct contact with the exhaust gas during operation.

19. The heat exchanger as recited in claim 18, wherein the thermoelectric module has at least one semiconductor element directly and integrally joined with the flow channel.

20. The heat exchanger as recited in claim 19, wherein multiple semiconductor elements of the thermoelectric module are directly and integrally joined with the flow channel.

21. The heat exchanger as recited in claim 19, wherein the thermoelectric module is situated radially on the outside of the flow channel.

22. The heat exchanger as recited in claim 19, further comprising:
a cooling channel provided for cooling the at least one thermoelectric module, wherein the cooling channel is thermally in contact with the thermoelectric module.

23. The heat exchanger as recited in claim 22, wherein the cooling channel is made from a ceramic material.

24. The heat exchanger as recited in claim 22, wherein the cooling channel is directly and integrally joined with the thermoelectric module.

25. The heat exchanger as recited in claim 22, wherein the at least one semiconductor element of the thermoelectric module is directly and integrally joined with the cooling channel.

26. The heat exchanger as recited in claim 25, wherein multiple semiconductor elements of the thermoelectric module are directly and integrally joined with the cooling channel.

27. The heat exchanger as recited in claim 22, wherein the cooling channel is situated essentially coaxially with the flow channel.

28. The heat exchanger as recited in claim 22, wherein at least one of the cooling channel and the flow channel is essentially ring-shaped.

29. A method for converting thermal energy of an exhaust gas of an internal combustion engine into electrical power, comprising:
providing a single flow channel for conveying the exhaust gas, wherein the flow channel is made from a ceramic material; and
thermally connecting at least one thermoelectric module for generating electrical power to the flow channel; and conveying the exhaust gas via the flow channel to the at least one thermoelectric module.
